(19) United States
(12) Patent Application Publication
(10) Pub. No.: US 2005/0083095 A1
(43) Pub. Date: Apr. 21, 2005

(54) Adaptive input/output buffer and methods thereof

(76) Inventors: Tsvika Kurts, Haifa (IL); Zelig Wayner, Haifa (IL)

Correspondence Address: EITAN, PEARL, LATZER & COHEN ZEDEK LLP, 10 ROCKEFELLER PLAZA, SUITE 1001, NEW YORK, NY, 10020, US

(21) Appl. No.: 10/685,418

(22) Filed: Oct. 16, 2003

(51) Int. Cl. H03H 11/26

(52) U.S. Cl. 327/276; 361/600

(57) ABSTRACT

A controller having programmable delay cells in its input/output channels may also include respective registers storing digital values that control the time delays introduced by the respective delay cells. The values programmed to the registers may be determined by testing the timing of signals between the controller and one or more devices coupled to the channels. The tests may include setting the registers with test values from a set of sequential test values, driving a particular pattern on the signals from the controller to the one or more devices, and checking whether portions of the pattern are received accurately by the one or more devices. Adjusting the timing of the signals may involve centering of the signals with respect to set up and hold time restrictions.

### BACKGROUND OF THE INVENTION

As frequencies used in digital systems increase, timing constraints become more difficult or even impossible to meet.

For example, common-clock bus protocols are used to transfer data, address and control signals between memory devices and a memory controller. These signals are sampled relative to a clock that is common to both the memory devices and the memory controller. As the period of that common clock decreases to the same order of the set-up and hold time requirements on the bus, manufacturing tolerances of the printed circuit board and the different semiconductors involved in the signal's timing may not be tight enough to ensure that all systems having a similar configuration will meet the timing requirements.

In addition, in “open” systems such as personal computers (PC), many different system configurations are possible, the systems having printed circuit boards from different sources and memory devices of different types and quantities. Each such configuration may have different timing characteristics, and these overall characteristics may extend beyond the timing tolerances of the memory controller.

Consequently, systems having particular configurations may fail to operate, while others may have marginal operation and may fail to operate in certain environmental conditions.

### BRIEF DESCRIPTION OF THE DRAWINGS

Embodiments of the invention are illustrated by way of example and not limitation in the figures of the accompanying drawings, in which:

FIG. 1 is a block diagram of a printed circuit board having installed thereon a device and a controller;

FIG. 2 and FIG. 3 are exemplary timing diagrams, helpful in understanding some embodiments of the invention;

FIG. 4 is a flowchart illustration of a method for setting and adjusting timing parameters;

FIG. 5 is a flowchart illustration of an exemplary method of generating lookup tables;

FIG. 6 is a flowchart illustration of an exemplary method for determining the digital values to program to a driving impedance control register and an output delay control register;

FIG. 7 is a flowchart illustration of an exemplary calibration sequence for the digital values to be programmed to the output delay control register and the input delay control register;

FIG. 8 is a flowchart illustration of an exemplary calibration algorithm for the digital values to be programmed to the output delay control register and the input delay control register;

FIG. 9 is a block diagram of an apparatus including a printed circuit board having a memory controller installed thereon;

FIGS. 10A-10D are flowchart illustrations of an exemplary calibration sequence for the digital values to be programmed to the delay control registers of the memory controller of FIG. 9; and

FIG. 11 is a simplified schematic illustration of an exemplary programmable delay cell, in accordance with some embodiments of the invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE INVENTION

In the following detailed description, numerous specific details are set forth in order to provide a thorough understanding of embodiments of the invention. However it will be understood by those of ordinary skill in the art that the embodiments of the invention may be practiced without these specific details. In other instances, well-known methods, procedures, components and circuits have not been described in detail so as not to obscure the invention.

Some portions of the detailed description that follows are presented in terms of algorithms and symbolic representations of operations on data bits or binary digital signals within a computer memory. These algorithmic descriptions and representations may be the techniques used by those skilled in the data processing arts to convey the substance of their work to others skilled in the art.

Some embodiments of the invention are directed to setting and/or dynamically adjusting parameters of physical components of a controller based on the attributes of one or more devices electrically coupled to the controller and based on the attributes of the medium electrically coupling the one or more devices to the controller. The physical components whose parameters are being set and/or adjusted may include those components which enable electrical signals sent by the controller to be accurately received by the one or more devices, and those components which enable electrical signals sent by the one or more devices to be accurately received by the controller.

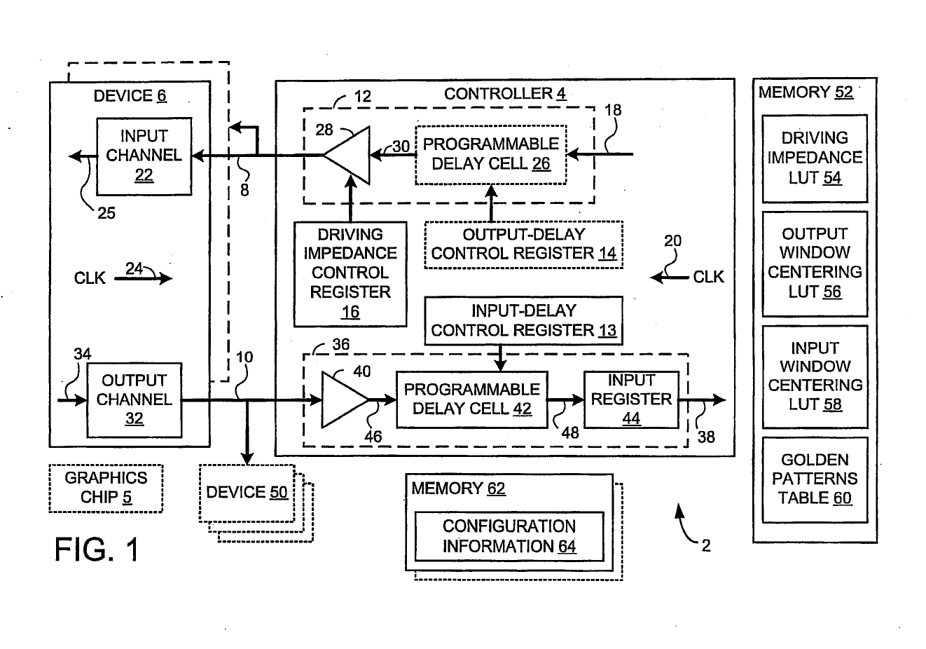

As shown in FIG. 1, a printed circuit board (PCB) 2 may comprise a controller 4, one or more devices 6, a conductor 8 and a conductor 10 according to some embodiments of the invention. PCB 2 may optionally comprise a graphics chip 5. A non-exhaustive list of examples for controller 4 includes a central processing unit (CPU) and a memory controller. For example, controller 4 may have the ability to drive control signals to perform Read and Write commands, and conductors 8 and 10 may be part of a bus for those control signals. A non-exhaustive list of examples for device 6 includes a memory device and a co-processor. The following description is for a single device 6, although the scope of the invention is not limited in this respect.

When device 6 is assembled on PCB 2, conductor 8 and conductor 10 may comprise traces on a printed circuit board. When device 6 is assembled on removable modules, conductor 8 and conductor 10 may comprise, for example, traces on a printed circuit board, traces on the removable module and the conductive connector that couples these traces.

The following description of embodiments of the invention makes reference to the rising edges of clocks. However, in other embodiments of the invention, reference could be made instead to the falling edges of the clocks.

### Parameters for Output Signals

The following description describes physical components of a controller and how to set and/or dynamically adjust parameters of these physical components to enable electrical signals sent by the controller to be accurately received by one or more devices electrically coupled to the controller. The setting and/or adjustment of these parameters may be based on the attributes of the one or more devices electrically coupled to the controller and based on the attributes of the medium electrically coupling the one or more devices to the controller.

Controller 4, which is an integrated circuit or a part of an integrated circuit, may comprise an output channel 12 controlled by an optional output-delay control register 14 and a driving impedance control register 16. Output channel 12 may receive from a digital subsystem (not shown) a signal 18 whose stabilized logic levels change no more than once during each period of a clock 20, and may generate an output signal on conductor 8 that may reflect the changes in the logic levels of signal 18.

Device 6 may comprise an input channel 22 that may receive a clock 24 and the signal on conductor 8 as inputs. Input channel 22 may sample the logic levels of the signal on conductor 8 on rising edges of clock 24 and may output-the sampled logic levels on a signal 25. One purpose of output channel 12, output-delay control register 14 and driving impedance control register 16 may be to ensure that changes in the logic levels of signal 18 are accurately reflected by changes in the logic levels of signal 25. Effectively, this will transfer signal 18 to signal 25.

The system formed by controller 4 and device 6 is a common-clock system.

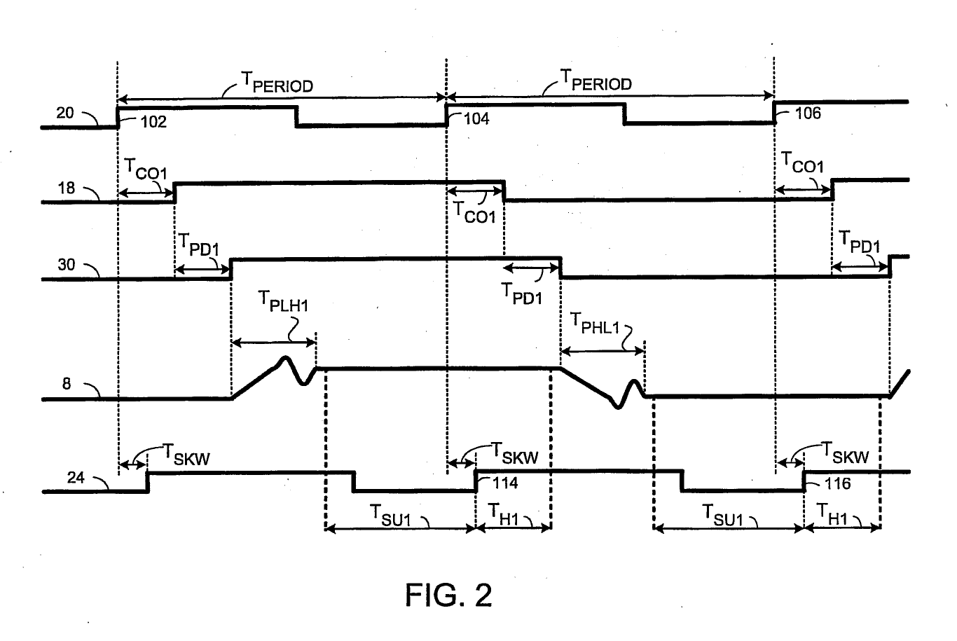

In the exemplary timing diagram of FIG. 2, clock 20 oscillates with period T_{PERIOD} nanoseconds (measured between rising edges, for example rising edges 102, 104 and 106). In this example, the logic level of signal 18 changes T_{CO1} nanoseconds after each rising edge of clock 20. In the exemplary timing diagram of FIG. 2, the time delay T_{CO1} is constant, although the scope of the invention is not limited in this respect.

Output channel 12 may comprise an optional programmable delay cell 26 and a programmable output buffer 28.

Programmable delay cell 26 may continuously sample the logic level of signal 18, and may continuously output logic levels on a signal 30 that are substantially equal to the logic levels sampled on signal 18. When a change in the logic level of signal 18 occurs, the logic level of signal 30 may change accordingly after a time delay T_{PD1}. Time delay T_{PD1} may be programmable within a time range, and may be set according to a digital value stored in output-delay control register 14, as will be explained in more detail hereinbelow.

Programmable output buffer 28 may receive signal 30 as input and may generate an output signal on conductor 8 that may reflect the changes in the logic levels of signal 30. Logic levels may be represented on conductor 8 by voltage levels. For example, a high voltage level may represent one logic level, and a low voltage level may represent another logic level. Consequently, programmable output buffer 28 may generate voltage levels on conductor 8 to reflect, the changes in the logic levels of signal 30.

Although the scope of the invention is not limited in this respect, programmable output buffer 28 may generate a low voltage level on conductor 8 by coupling a low-voltage source (ground, for example) to conductor 8 through a sink driving impedance, internal to programmable output buffer 28. Similarly, programmable output buffer 28 may generate a high voltage level on conductor 8 by coupling a high-voltage source to conductor 8 through a source driving impedance, internal to programmable output buffer 28.

Driving impedance control register 16 may be coupled to programmable output buffer 28, and digital values stored in driving impedance control register 16 may control the source driving impedance and the sink driving impedance of programmable output buffer 28. (Alternatively, driving impedance control register 16 could be replaced by two registers, one to store a digital value that may control the source driving impedance of programmable output buffer 28, and the other to store a digital value that may control the sink driving impedance of programmable output buffer 28.)

Since a low-to-high transition time T_{PLH1} (high-to-low transition time T_{PHL1})—during which the voltage of the signal on conductor 8 may not properly represent any logic level—may be affected by the source driving impedance (sink driving impedance) of programmable output buffer 28, driving impedance control register 16 may control the low-to-high transition time T_{PLH1} and the high-to-low transition time T_{PHL1} of the signal on conductor 8. Moreover, low-to-high transition time T_{PLH1} and high-to-low transition time T_{PHL1} may be affected by the physical layout topology of conductor 8, by the total capacitive load on conductor 8, by the impedance of conductor 8, and by the input impedance of input channel 22.

An exemplary timing diagram of clock 24 is shown in FIG. 2, although the invention is not limited to this example. In this example, clock 24 may oscillate at the same frequency as clock 20, having a period of T_{PERIOD} nanoseconds (measured between rising edges), and the rising edges of clock 24 may have a constant time shift of T_{SKW} nanoseconds from the rising edges of-clock 20.

When output channel 12 generates a logic level on conductor 8 after a rising edge of clock 20, input channel 22 ought to sample that logic level at the rising edge of clock 24 shifted T_{SKW} nanoseconds from the following rising edge of clock 20.

For example, when output channel 12 generates a high logic level (low logic level) on conductor 8 after rising edge 102 (104) of clock 20, input channel 22 ought to sample that logic level on rising edge 114 (116) of clock 24.

For input channel 22 to correctly sample logic levels of the signal on conductor 8, the voltage of the signal on conductor 8 may have to be stable with the corresponding voltage levels for at least a “setup time” T_{SU1} before the rising edge of clock 24 and may have to remain stable with this voltage level for at least a “hold time” T_{H1} after the rising edge of clock 24.

In other words, for input channel 22 to correctly sample a high (low) logic level of the signal on conductor 8, the following conditions must be fulfilled:
(a) the high (low) voltage of the signal on conductor 8 must be stable for a time period equivalent to at least the sum of the setup time and the hold time;
(b) the high (low) voltage of the signal on conductor 8 must be stable for at least T_{H1} after the rising edge of clock 24; and
(c) the high (low) voltage of the signal on conductor 8 must be stable for at least T_{SU1} before the rising edge of clock 24.
   Condition (a) May be Expressed by the Following Relations for High Voltages and for Low Voltages:
   T_{PERIOD}−T_{PLH1}≧T_{SU1}+T_{H1}; 1.
   T_{PERIOD}−T_{PHL1}≧T_{SU1}+T_{H1}. 1′.
   Condition (b) May be Expressed by the Following Relation (the Same Relation for High and Low Voltages):
   T_{CO1}+T_{PD1}≧T_{H1}+T_{SKW}. 2.
   Condition (c) May be Expressed by the Following Relations for High Voltages and for Low Voltages:
   T_{PERIOD}−T_{CO1}−T_{PD1}−T_{PLH1}≧T_{SU1}−T_{SKW}. 3.
   T_{PERIOD}−T_{CO1}−T_{PD1}−T_{PHL1}≧T_{SU1}−T_{SKW}. 3′.

Conditions (b) and (c) may be expressed as upper and lower limits on the time delay T_{PD1} introduced by programmable delay cell 26, as expressed by the following relations:
T_{PERIOD}−T_{PLH1}−T_{CO1}−T_{SU1}+T_{SKW}≧T_{PD1}≧T_{H1}+T_{SKW}−T_{CO1}. 4.
T_{PERIOD}−T_{PHL1}−T_{CO1}−T_{SU1}+T_{SKW}≧T_{PD1}≧T_{H1}+T_{SKW}−T_{CO1}. 5.

It can be shown that relation 1 is a necessary but not sufficient condition for both relations 2 and 3 to be fulfilled when sampling a high voltage. Similarly, relation 1′ is a necessary but not sufficient condition for both relations 2 and 3′ to be fulfilled when sampling a low voltage. Consequently once the digital values programmed to driving impedance control register 16 are adjusted so that relations 1 and 1′ are fulfilled, the digital values programmed to output-delay control register 14 may be adjusted so that both relations 4 and 5 are fulfilled.

Controllable parameters of relations 1, 1′, 4 and 5 (emphasized in bold type in the relations) may be adjusted via digital values programmed to driving impedance control register 16 and output delay control register 14 to compensate for the variations in all other parameters in the relations so that conditions (a), (b), and (c) are fulfilled, as will be explained hereinbelow.

Relations 1 and 1′

T_{PERIOD} is a fixed value, while the exact values of setup time T_{SU1} and hold time T_{H1} may be affected, for example, by manufacturing tolerances of device 6 and may vary with, for example, variations in the ambient temperature. By adjusting the source (sink) driving impedance of programmable output buffer 28, the low-to-high transition time T_{PLH1} (high-to-low transition time T_{PHL1}) may be adjusted so that relation 1 (1′) is satisfied, i.e. a high flow) voltage of the signal on conductor 8 is stable for a time period equivalent to at least the sum of the setup time T_{SU1} and the hold time T_{H1}.

It should be understood that the low-to-high transition time T_{PLH1} (high-to-low transition time T_{PHL1}) is not determined solely by the source (sink) driving impedance of programmable output buffer 28. Rather, the exact values of low-to-high transition time T_{PLH1} and high-to-low transition time T_{PHL1} may be affected by, as previously explained, the total capacitive load on conductor 8, the physical layout topology of conductor 8, the impedance of conductor 8, and the input impedance of input channel 22. Furthermore, the total capacitive load on conductor 8 may vary, for example, according to the number and type of devices 6 coupled to conductor 8, and according to manufacturing tolerances of each device 6. The physical layout topology of conductor 8 may vary, for example, according to the number of devices 6 coupled to conductor 8 and according to the design of PCB 2. The impedance of conductor 8 may vary, for example, according to the design of PCB 2 and according to manufacturing tolerances of PCB 2. The input impedance of input channel 22 may vary, for example, according to the type and manufacturing tolerances of device 6.

Since there are so many different factors that may affect the other parameters in relations 1 and 1′, the ability to control the low-to-high transition time T_{PLH1} and the high-to-low transition time T_{PHL1} enables relations 1 and 1′ to be fulfilled in various situations.

Relations 4 and 5

T_{PERIOD} is a fixed value, and low-to-high transition time T_{PLH1} and the high-to-low transition time T_{PHL1} will have been adjusted before attempting to satisfy relations 4 and 5. However, as discussed hereinabove with respect to relations 1 and 1′, setup time T_{SU1} and hold time T_{H1} may be affected, for example, by manufacturing tolerances of device 6 and may vary with, for example, variations in the ambient temperature. Similarly, the exact value of time delay T_{CO1} may be affected by, for example, manufacturing tolerances of controller 4 and may vary with, for example, variations in the ambient temperature. Moreover, the exact value of the time shift T_{SKW} between the rising edges of clock 20 and clock 24 may be affected by, for example, the methods used to generate clock 20 and clock 24. For example, clock 24 may be generated by a phase locked loop (PLL) that is locked to clock 20 and has a constant or varying phase error. In another example, the time shift T_{SKW} may occur as a result of skew between signals in a clock distribution tree (not shown) used to generate clock 20 and clock 24, or by a difference in rise time of signals of that clock distribution tree.

Consequently, for input channel 22 to correctly sample logic levels of the signal on conductor 8, after adjusting the sink driving impedance and the source driving impedance of programmable output buffer 28 so that relations 1 and 1′ are fulfilled, delay T_{PD1} of programmable delay cell 26 may be adjusted by setting the appropriate digital value in output-delay control register 14, so that both relations 4 and 5 are fulfilled.

### Parameters for Input Signals

The following description describes physical components of a controller and how to set and/or dynamically adjust parameters of these physical components to enable electrical signals sent by one or more devices electrically coupled to the controller to be accurately received by the controller. The setting and/or adjustment of these parameters may be based on the attributes of the one or more devices electrically coupled to the controller and based on the attributes of the medium electrically coupling the one or more devices to the controller.

Device 6 may comprise an output channel 32. Output channel 32 may receive a signal 34 whose stabilized logic levels change no more than once during each period of clock 24, and may generate an output signal on conductor 10 that may reflect the changes in the logic levels of signal 34. Logic levels may be represented on conductor 10 by voltage levels.

Controller 4 may comprise an input channel 36 controlled by an input-delay control register 13. Input channel 36 may receive clock 20 and the signal of conductor 10 as inputs, and may output a signal 38. Input channel 36 may sample the logic levels of the signal on conductor 10 on rising edges of clock 20 and may output the sampled logic levels on signal 38. One purpose of input channel 36 and input-delay control register 13 may be to ensure that changes in the logic levels of signal 34 are accurately reflected by changes in the logic levels of signal 38. Effectively, this will transfer signal 34 to signal 38.

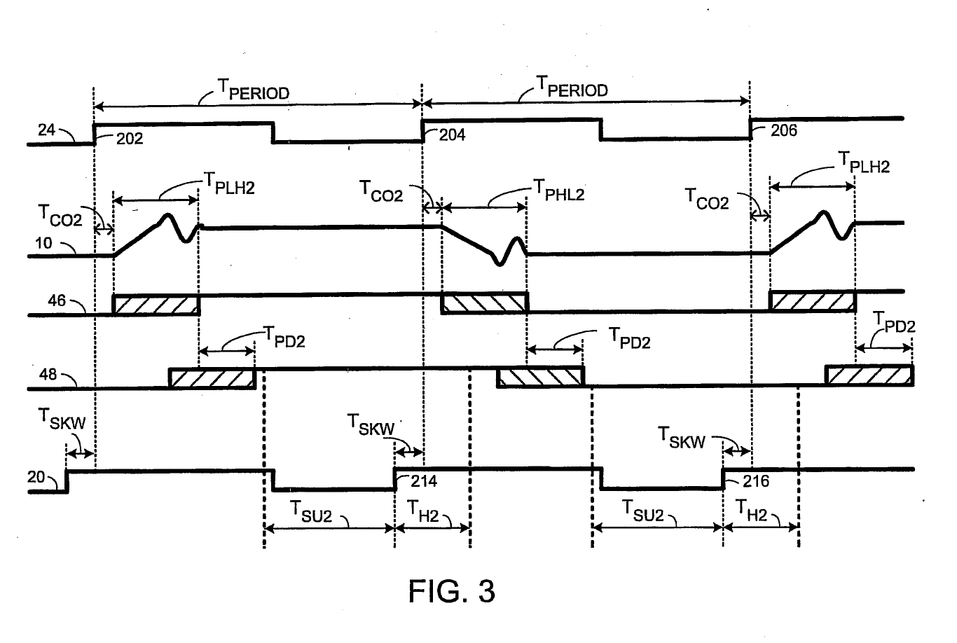

In the exemplary timing diagram of FIG. 3, clock 24 oscillates with period T_{PERIOD} nanoseconds (measured between rising edges). In this example, the logic level of the signal on conductor 10 begins to change T_{CO2} nanoseconds after each rising edge of clock 24. In the exemplary timing diagram of FIG. 3, the time delay T_{CO2} is constant, although the scope of the invention is not limited in this respect.

In addition, the transition of the signal on conductor 10 from a low voltage level to a high voltage level may be characterized by a low-to-high transition time T_{PLH2}, during which the voltage of the signal on conductor 10 may not properly represent any logic level. Similarly, the transition of the signal on conductor 10 from a high voltage level to a low voltage level may be characterized by a high-to-low transition time T_{PHL2} during which the voltage of the signal on conductor 8 may not properly represent any logic level.

The low-to-high transition time T_{PLH2} may be affected by the source driving impedance of output channel 32, the total capacitive load on conductor 10, the physical layout topology of conductor 10, the impedance of conductor 10, and the input impedance of input channel 36.

Similarly, the high-to-low transition time T_{PHL2} may be affected by the sink driving impedance of output channel 32, the total capacitive load on conductor 10, the physical layout topology of conductor 10, the sink driving impedance of output channel 32, the impedance of conductor 10, and the input impedance of input channel 36.

In the exemplary timing diagram of FIG. 3, the voltage on conductor 10 achieves a stabilized high voltage level (T_{CO2}+T_{PLH2}) nanoseconds after a rising edge 202 of clock 24, and achieves a stabilized low voltage level (T_{CO2}+T_{PHL2}) nanoseconds after a rising edge 204 of clock 24, and achieves a stabilized high voltage level (T_{CO2}+T_{PLH2}) nanoseconds after a rising edge 206 of clock 24.

Input channel 36 may comprise an input buffer 40, a programmable delay cell 42 and an input register 44. Input register 44 is a part of a front end for the digital subsystem (not shown).

In some embodiments, input buffer 40 may receive the signal on conductor 10 as input and may generate an output signal 46 that may reflect the changes in the logic levels of the signal on conductor 10. When the voltage of the, signal on conductor 10 represents a particular logic level, input buffer 40 may output the same logic level on signal 46. However, when the voltage of the signal on conductor 10 does not properly represent any logic level, such as, for example during the time periods T_{PLH2} and T_{PHL2}, signal 46 may also not properly represent any logic level, as illustrated in FIG. 3 by a hatched rectangle. (n other embodiments, input buffer 40 may have a different behavior. For example, input buffer 40 may be a Schmitt trigger input buffer, for which signal 46 always represents a proper logic level, but the time at which the logic level changes may vary according to the rise time or the fall time.)

Programmable delay cell 42 may receive signal 46 as input and may output a signal 48. Programmable delay cell 42 may continuously sample the logic level of signal 46, and may continuously output logic levels on signal 48 that are substantially equal to the logic levels sampled on signal 46. When a change in the logic level of signal 46 occurs, the logic level of signal 48 may change accordingly after a time delay T_{PD2}. Time delay T_{PD2} may be programmable, and may be set according to a digital value stored in input delay control register 13.

Input register 44 may sample the logic levels of signal 48 on rising edges and may output signal 38. The logic level input register 44 may output on signal 38 after each rising edge of clock 20 may be substantially equal to the logic level sampled on signal 48 at the rising edge of clock 20.

When output channel 32 generates a logic level on conductor 10 after a rising edge of clock 24, input register 44 ought to sample that logic level on signal 48 at the rising edge of clock 20 shifted T_{SKW} nanoseconds from the following rising edge of clock 24.

For example, when output channel 32 generates a high logic level on conductor 10 after rising edge 202 of clock 24, input register 44 ought to sample that logic level on signal 48 on rising edge 214 of clock 20. Similarly, when output channel 32 generates a low logic on conductor 10 after rising edge 204 of clock 24, input register 44 ought to sample that logic level on signal 48 on rising edge 216 of clock 20.

For input register 44 to correctly sample logic levels of signal 48, the logic level of signal 48 may have to be stable for at least a “setup time” T_{SU2} before the rising edge of clock 20 and may have to remain stable for at least a “hold time” T_{H2} after the rising edge of clock 20.

In other words, for input register 44 to correctly sample a high (low) logic level of signal 48, the following conditions must be fulfilled:

(d) the high (low) voltage of signal 48 must be stable for a time period equivalent to at least the sum of the setup time and the hold time;

(e) the high (low) voltage on signal 48 must be stable for at least T_{H2} after the rising edge of clock 20; and

(f) the high (low) voltage on signal 48 must be stable for at least T_{SU2} before the rising edge of clock 20.

Condition (d) May be Expressed by the Following Relations for High Voltages and for Low Voltages:
T_{PERIOD}−T_{PLH2}≧T_{SU2}+T_{H2}; 6.
T_{PERIOD}−T_{PHL2}≧T_{SU2}+T_{H2}. 6′.
Condition (e) May be Expressed by the Following Relation (the Same Relation for High and Low Voltages):
T_{CO2}+T_{PD2}+T_{SKW}≧T_{H}. 7.
Condition (f) May be Expressed by the Following Relations for High Voltages and Low Voltages:
T_{PERIOD}−T_{CO2}−T_{PD2}−T_{PLH2}≧T_{SU2}+T_{SKW}. 8.
T_{PERIOD}−T_{CO2}−T_{PD2}−T_{PHL2}≧T_{SU2}+T_{SKW}. 8′

Conditions (e) and (f) may be expressed as upper and lower limits on the time delay T_{PD2} introduced by programmable delay cell 42, as expressed by the following relations:
T_{PERIOD}−T_{PLH2}−T_{CO2}−T_{SU2}−T_{SKW}≧T_{PD2}≧T_{H2}−T_{SKW}−T_{CO2}. 9.
T_{PERIOD}−T_{PHL2}−T_{CO2}−T_{SU2}−T_{SKW}≧T_{PD2}≧T_{H2}−T_{SKW}−T_{CO2}. 10.

The controllable parameter of relations 9 and 10 (emphasized in bold type in the relations) may be adjusted via digital values programmed to input delay control register 13 to compensate for the variations in all other parameters in the relations so that conditions (e), and (f) are fulfilled, as will be explained hereinbelow.

Relations 6 and 6′

According to embodiments of this invention, low-to-high transition time T_{PLH2} and high-to-low transition time T_{PHL2} are not controllable by controller 4, and therefore relations 6 and 6′ are assumed to be fulfilled.

Relations 9 and 10

T_{PERIOD} is a fixed value, while the exact values of setup time T_{SU2} and hold time T_{H2} may be affected, for example, by manufacturing tolerances of controller 4 and may vary with, for example, variations in the ambient temperature. Similarly, the exact value of time delay T_{CO2} may be affected by, for example, manufacturing tolerances of device 6 and may vary with, for example, variations in the ambient temperature. Moreover, the exact value of the time shift of T_{SKW} between the rising edges of clock 20 and clock 24 may be affected by, for example, the methods used to generate clock 20 and clock 24.

The exact values of low-to-high transition time T_{PLH2} and high-to-low transition time T_{PHL2} may be affected by the total capacitive load on conductor 10, the physical layout topology of conductor 10, the impedance of conductor 10, and the input impedance of input channel 36. Furthermore, the total capacitive load on conductor 10 may vary, for example, according to variations in the output capacitance of output channel 32, and according to the type and manufacturing tolerances of each device 6. In addition, the total capacitive load on conductor 10 may vary, for example, according to the type, the number and manufacturing tolerances of optional device(s) 50 electrically connected to conductor 10. The physical layout topology of conductor 10 may vary, for example, according to the design of PCB 2. The impedance of conductor 10 may vary, for example, according to the design of PCB 2 and according to manufacturing tolerances of PCB 2. The output impedance of output channel 32 may vary, for example, according to manufacturing tolerances of device 6.

Consequently, for input register 44 to correctly sample logic levels of signal 48, delay T_{PD2} of programmable delay cell 42 may be adjusted by setting the appropriate digital value in input-delay control register 13, so that both relations 9 and 10 are fulfilled.

### Setting and Adjusting Parameters

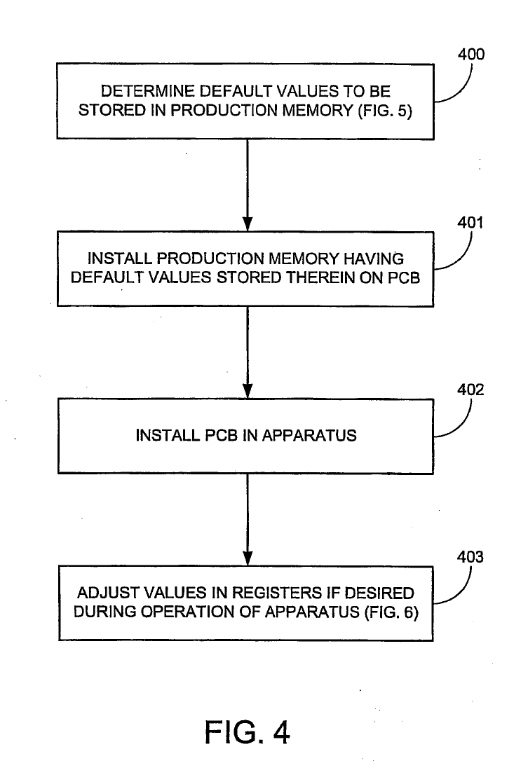

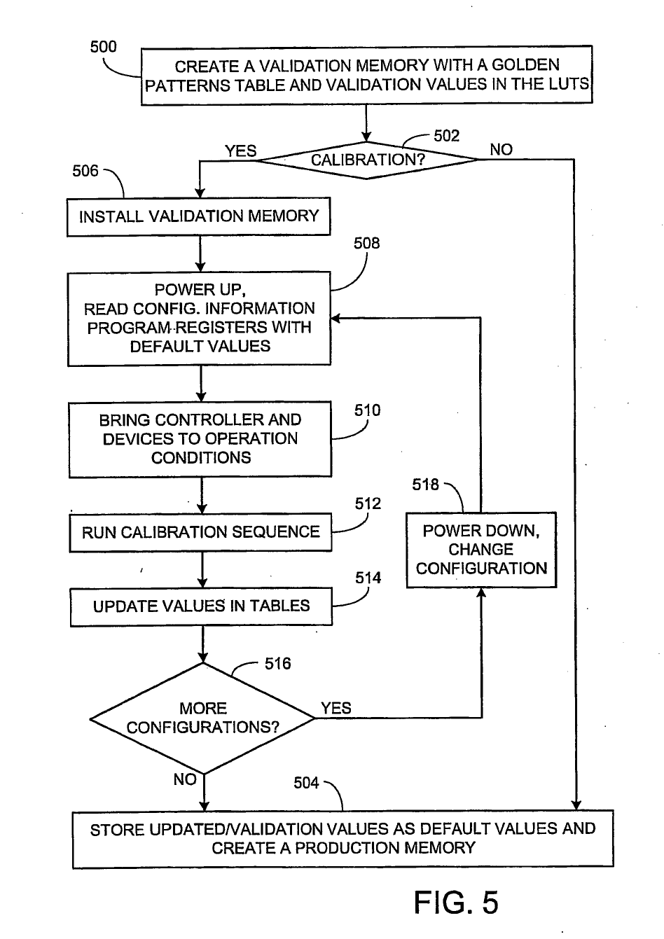

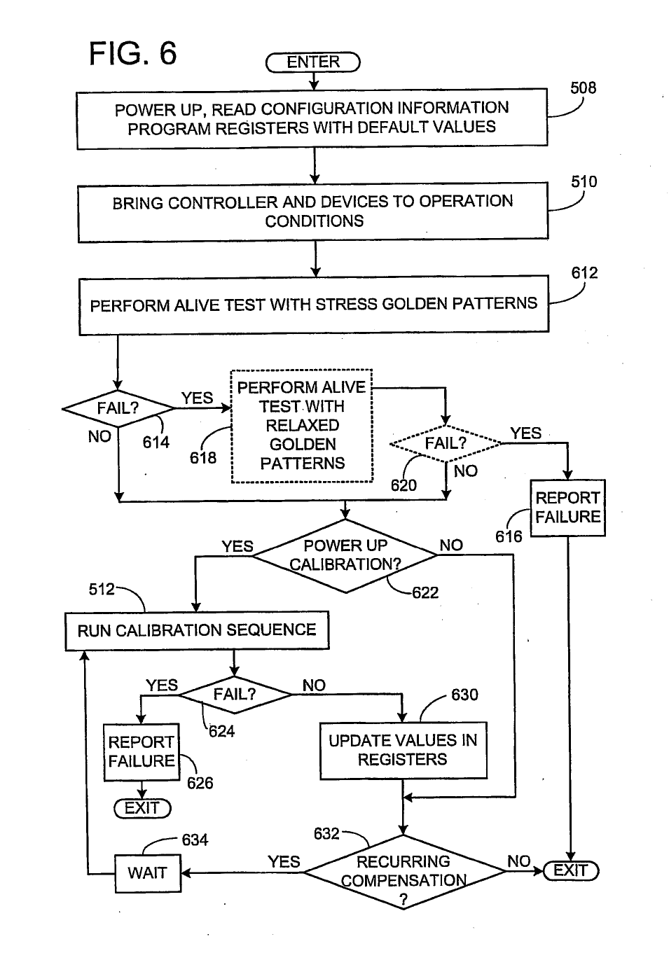

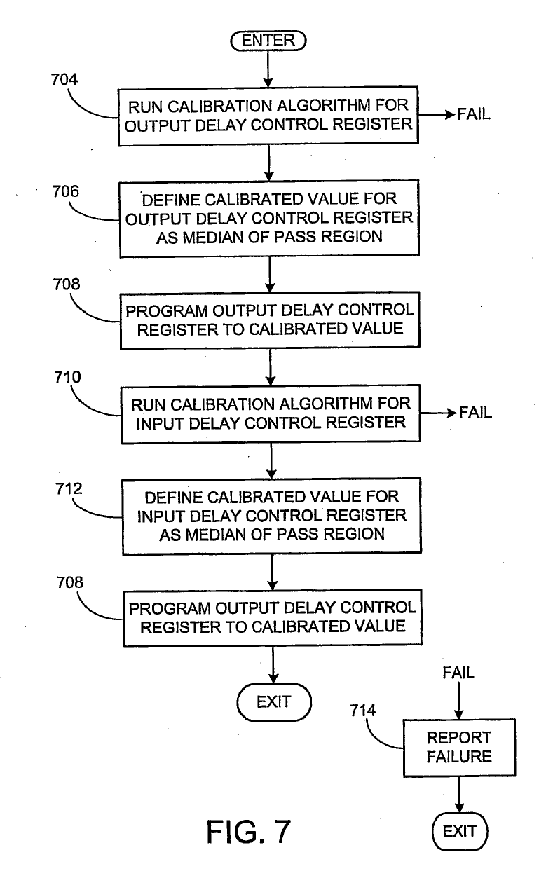

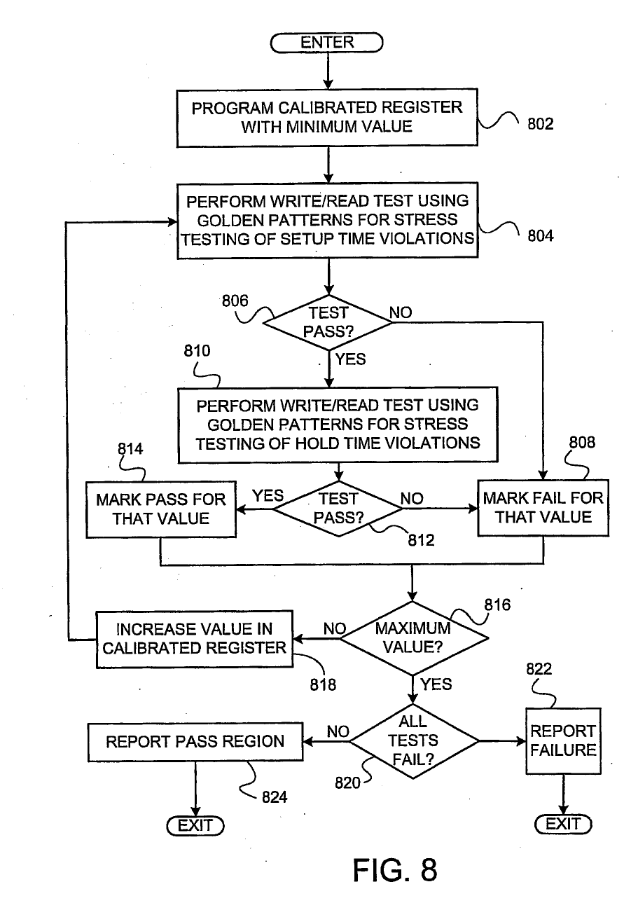

The parameters of the physical components of the controller are determined by the digital values in input-delay control register 13, output-delay control register 14 and driving impedance control register 16. As shown in FIG. 4, default values for these registers may be determined by laboratory work (-400-) and stored in a memory installed on the printed circuit board (-401-). The printed circuit board may be installed in an apparatus (-402-), and the digital values stored in the registers may be adjusted if desired during the operation of the apparatus (-403-). As will be explained in further detail hereinbelow, FIG. 5 is a more detailed description of -400-, while FIG. 6 is a more detailed description of -403-. FIG. 7 describes a method called by the methods of FIG. 5 and FIG. 6, while FIG. 8 describes a method called by the method of FIG. 7.

PCB 2 may comprise one or more memories 62 to store configuration information 64 about PCB 2. Configuration information 64 may include information that affects the digital values to program to driving impedance control register 16 and output delay control register 14, such as, for example, the type and number of devices 6 electrically coupled to conductor 8, and optionally, information about the topology and impedance of conductor 8. Configuration information 64 may also include information that affects the digital values to program to input delay control register 13, such as, for example, the type of device 6 sending electrical signals on conductor 10, the type and number of optional devices 50 electrically coupled to conductor 10, and optionally, information about the topology and impedance of conductor 10.

PCB 2 may comprise a memory 52 to store information used to program driving impedance control register 16 and output delay control register 14, and to program input delay control register 13. Alternatively, memory 52 may be part of controller 4. Such information may be arranged, for example, in the following data structures: a driving impedance lookup table (LUT) 54, an output window centering lookup table 56, an input window centering lookup table 58 and a golden patterns table 60. The data in all or some of the data structures of memory 52 may be programmable. In addition, memory 52 may comprise one or more memory devices, and the data structures may be distributed among these devices.

Memory 52 may also comprise software modules to implement the methods of FIG. 6, FIG. 7, and FIG. 8.

Driving impedance LUT 54 may comprise one or more entries. An entry for a particular total capacitive load on conductor 8, a particular impedance of conductor 8 and a particular input impedance of input channel 22, may include a digital value to control the source driving impedance of programmable output buffer 28 and another digital value to control the sink driving impedance of programmable output buffer 28 that enable condition (a) to be fulfilled.

Output window centering LUT 56 may comprise one or more entries. An entry for a particular total capacitive load on conductor 8, a particular time shift T_{SKW}, a particular impedance of conductor 8 and a particular input impedance of input channel 22, may include a digital value to control the time delay T_{PD1} introduced by programmable delay cell 26 that enables conditions (b) and (c) to be fulfilled.

Input window centering LUT 58 may comprise one or more entries; An entry for a particular total capacitive load on conductor 10, a particular time shift T_{SKW}, a particular impedance of conductor 10 and a particular input impedance of input channel 36, may include a digital value to control the time delay T_{PD2} introduced by programmable delay cell 42 that enables conditions (e) and (f) to be fulfilled.

Golden patterns table 60 may contain patterns of digital values used for testing whether input channel 22 correctly samples logic levels of the signal on conductor 8. For example, golden patterns table 60 may include patterns designed for relaxed/stress testing of hold time/set-up time violations. The precise patterns to be used may depend on many factors, such as, for example, the specific topology of conductor 8 and the protocol in which digital values are transferred over conductor 8. However, when these patterns of digital values for hold (set-up) time violations are generated on conductor 8 and time delay T_{PD1} is close to the minimum (maximum) of its range, input channel 22 may be more likely to correctly sample logic levels of the signal on conductor 8 for the relaxed testing pattern than for the stress testing pattern.

Similarly, golden patterns table 60 may contain patterns of digital values used for testing whether input register 44 correctly samples logic levels of the signal on conductor 10. For example, golden patterns table 60 may include patterns designed for relaxed/stress testing of hold/set-up time violations. The precise patterns to be used may depend on many factors, such as, for example, the specific topology of conductor 10 and the protocol in which digital values are transferred over conductor 10. However, when these patterns of digital values for hold (set-up) time violations are generated on conductor 10 and time delay T_{PD2} is close to the minimum (maximum) of its range, input register 44 may be more likely to correctly sample logic levels of the signal on conductor 10 for the relaxed testing pattern than for the stress testing pattern.

Moreover, golden patterns table 60 may be programmable, and its content may be updated or replaced, if desired, as patterns providing more effective testing are developed.

FIG. 5 is a flowchart illustration of an exemplary method of determining the default values to be stored in driving impedance LUT 54, output window centering LUT 56 and input window centering LUT 58, according to some embodiments of the invention. Although the scope of the invention is not limited in this respect, the method of FIG. 5 may be performed prior to mass production of the combination of a particular type of PCB 2 and memory 52 installed thereon.

A “validation” version of memory 52 may be generated (-302-), for example, using simulations and validation tests of controller 4 to determine “validation” digital values stored in the entries of driving impedance lookup table 54, output window centering lookup table 56 and input window centering lookup table 58.

However, due to, for example, manufacturing tolerances of PCB 2, controller 4, devices 6, and optional devices 50, one or more of the timing parameters related to the signal on conductor 8 (T_{CO1}, T_{PD1}, T_{PHL1}, T_{PLH1}, T_{SU1}, T_{H1} and T_{SKW}), and one or more of the timing parameters related to the signal on conductor 10 (T_{CO2}, T_{PD2}, T_{PHL2}, T_{PLH2}, T_{SU2}, T_{H2} and T_{SKW}) may have values that deviate from the values used during the simulation and validation tests to define the “validation” digital values stored in the validation version of memory 52. Consequently, the digital values stored in the validation version of memory 52 may not be adequate for input channel 22 to correctly sample logic levels of the signal on conductor 8 and for input register 44 to correctly sample logic levels of the signal on conductor 10 under certain operating conditions.

If calibration of the entries of tables 54, 56 and 58 is not desired (-502-), the validation version of memory 52 may be used as a “production” version of memory 52 (-504-). Therefore, the default values for the registers are the validation values.

If calibration is desired (-502-), the “validation” version of memory 52 may be installed on PCB 2 (-506-). PCB 2 may be powered up and configuration information 64 may then be read. The appropriate entries of driving impedance lookup table 54, output window centering lookup table 56 and input window centering lookup table 58 of the validation memory are selected based on the configuration information 64, and the digital values in the selected entries may be programmed to driving impedance control register 16, output delay control register 14 and input delay control register 13, respectively (-508-).

Controller 4 and devices 6 may be brought to operating conditions (-510-). For example, controller 4 and devices 6 may be heated to an operating temperature, such as, for example, 50° C., by, for example, toggling the signal on conductor 8 and the signal on conductor 10. When the desired temperature is reached, a calibration sequence, to be described in more detail with respect to FIG. 7, may be performed (-512-) to determine digital values for driving impedance lookup table 54 and output window centering lookup table 56 that are calibrated to the specific parameters of PCB 2 and to the specific parameters of devices 6 and controller 4 that are installed on PCB 2. In addition, a similar calibration sequence may be performed (-512-) to determine digital values for input window centering lookup table 58 that are calibrated to the specific parameters of PCB 2 and to the specific parameters of devices 6, optional devices 50 and controller 4 that are installed on PCB 2.

The appropriate entries of one or more of driving impedance lookup table 54, output window centering lookup table 56 and input window centering lookup table 58 may be updated with values determined by the calibration sequences (-514-), and a production version of memory 52 with the updated values as the default values for the registers may be created (-504-).

Moreover, if different configurations of PCB 2 are possible (for example, controller 4 and optional devices 50 may be permanently installed on PCB 2 while different configurations of PCB 2 may have different types and numbers of devices 6) and it is desired to have the tables of memory 52 store entries appropriate for each of the different configurations, then the calibration process (-508- through -514-) may be repeated for each of the configurations (-516- and -518-) prior to creating the production version of memory 52 to be installed on PCB 2 (-504-).

FIG. 6 is a flowchart illustration of an exemplary method according to some embodiments of the invention, for determining the digital values to program to driving impedance control register 16 and output delay control register 14 so that input channel 22 correctly samples logic levels of the signal on conductor 8, and for determining the digital values to program to input delay control register 13, so that input register 44 correctly samples logic levels of the signal on conductor 10.

Although the scope of the invention is not limited in this respect, the method of FIG. 6 may be performed each time an apparatus including the PCB 2 of FIG. 1 is powered up. PCB 2 already has installed on it controller 4, one or more devices 6, optional devices 50, memory 62 and a production version of memory 52.

PCB 2 may be powered up and configuration information 64 may then be read. The appropriate entries of driving impedance lookup table 54, output window centering lookup table 56 and input window centering lookup table 58 of the validation memory may be selected based on the configuration information 64, and the digital values in the selected entries may be programmed to driving impedance control register 16, output delay control register 14 and input delay control register 13, respectively (-508-).

Controller 4 and devices 6 may be brought to operating conditions (-510-). For example, controller 4 and devices 6 may be heated to an operating temperature, such as, for example 50° C., by, for example, toggling the signal on conductor 8 and the signal on conductor 10.

When the desired temperature is reached, it is tested that input channel 22 correctly samples logic levels of the signal on conductor 8, and that input register 44 correctly samples logic levels of the signal on conductor 10, using the patterns stored in golden patterns table 60 that are designed for stress testing of hold time and setup time violations (-612-). If the test fails (-614-), the method may exit while reporting the failure (-616-). Optionally, before exiting, the test may be repeated using the patterns stored in golden patterns table 60 that are designed for relaxed testing of hold time and setup time violations (-618-). If the repeated test fails (-620-), the method may exit while reporting the failure (-616-).

However, if the stress tests do not fail, or if the relaxed tests do not fail, the method may continue to decision -622- regarding power-up calibration.

If power-up calibration of the digital values in driving impedance control register 16 and output window delay control register 14 is desired (-622-), a calibration sequence, described in more detail with respect to FIG. 7, may be performed (-512-) to determine digital values for driving impedance control register 16 and output window delay control register 14 that are calibrated to the current parameters of PCB 2 and to the current parameters of devices 6 and controller 4 that are installed on PCB 2.

In addition, a similar calibration sequence may be performed (-512-) to determine a digital value for input delay control register 13 that is calibrated to the current parameters of PCB 2 and to the current parameters of devices 6, optional devices 50 and controller 4 that are installed on PCB 2.

If the calibration fails (-624-), the method may exit while reporting the failure (-626-). However, if the calibration does not fail, and if the calibration sequence determines for at least one of driving impedance control register 16, output delay control register 14 and input delay control register 13, a value which is different from the default value programmed in -508-, the contents of the corresponding register(s) will be replaced with the value(s) determined by the calibration sequence (-630-).

During operation of controller 4 and devices 6, changes in the ambient temperature, drifts in the supply voltage to controller 4 and to devices 6 and other factors may result in changes in the timing parameters of the signals on conductors 8 and 10. To compensate for such changes, calibrating the contents of registers 13, 14 and 16 (-512-) may be repeated on a recurring basis, if desired (-632- and -634-). This repetition of the calibration may occur even if power-up calibration is not desired (-622-).

It should be noted that even if the default values stored in memory 52 and programmed to the registers at power-up based on configuration information 64 result in the success of the alive test with stress golden patterns or the alive test with relaxed golden patterns, the alive test may succeed with a small margin. By calibrating the values using a calibration sequence and updating the registers with the calibrated values, this margin for success in passing the test with golden patterns may be increased.

FIG. 7 is a flowchart illustration of an exemplary calibration sequence for the digital values to be programmed to output delay control register 14 and input delay control register 13, according to some embodiments of the invention. The calibration sequences -512- referred to by the methods of FIG. 5 and FIG. 6 may include the sequence of FIG. 7, although the scope of the invention is not limited in this respect.

When the sequence of FIG. 7 is called by the method of FIG. 5, input delay control register 13 and output delay control register 14 are already programmed with default values from input centering lookup table 58 and output centering lookup table 56, respectively, the default values having been selected from the tables according to the configuration information 64 at -508- of FIG. 5.

Similarly, when the sequence of FIG. 7 is called by the method of FIG. 6, input delay control register 13 and output delay control register 14 are already programmed, either with default values from lookup tables selected according to the configuration information 64 at -508- of FIG. 6, or with values determined by a previous call to the calibration sequence of FIG. 7 at -630- of FIG. 6.

A calibration algorithm may be performed for the value of output delay control register 14 (-704-). As will be explained hereinbelow with respect to FIG. 8, the calibration algorithm may determine one or more values for output delay control register 14 at which input channel 22 correctly samples logic levels of the signal on conductor 8. The calibrated value for output delay control register 14 may be selected as the median of these values (-706-).

Output delay control register 14 may then be programmed with the calibrated value (-708-), and a calibration algorithm may be performed for the value of input delay control register 13 (-710-). The calibration algorithm may determine one or more values for input delay control register 13 at which input register 44 correctly samples logic levels of the signal on conductor 10. The calibrated value for input delay control register 13 may be selected as the median of these values (-712-).

However, if the calibration algorithm (-704-) cannot determine any values for output delay control register 14 at which input channel 22 correctly samples logic levels of the signal on conductor 8 the method will report a failure (-714-) and exit.

Similarly, if the calibration algorithm (-710-) cannot determine any values for input delay control register 13 at which input register 44 correctly samples logic levels of the signal on conductor 10, the method will report a failure (-714-) and exit.

FIG. 8 is a flowchart illustration of an exemplary calibration algorithm for the digital values to be programmed to output delay control register 14 and input delay control register 13, according to some embodiments of the invention. The calibration algorithms referred to by the method of FIG. 6 at -704- and -710- may include the algorithm of FIG. 8, although the scope of the invention is not limited in this respect

The register to be calibrated (output delay control register 14 at -704- of FIG. 7, and input delay control register 13 at -710- of FIG. 7) is programmed to a value that corresponds to the delay cell controlled by the register having the minimum delay of its range (-802-).

In a first test, a pattern designed for stress testing of setup time violations is sent via signal 18 to device 6, and sent back from signal 34 to controller 4 (-804-). If the digital values received on signal 38 differ from the digital values sent via signal 18 (-806-), the programmed value is marked fail (-808-). However, if the digital values received on signal 38 match the digital values sent from signal 18 (-806-), a second test is performed.

In the second test, a pattern designed for stress testing of hold time violations is sent via signal 18 to device 6, and sent back from signal 34 to controller 4 (-810-). If the digital values received on signal 38 differ from the digital values sent via signal 18 (-812-), the programmed value is marked fail (-808-). However, if the digital values received on signal 38 match the digital values sent from signal 18 (-806-), the programmed value is marked pass (-814-).

The register to be calibrated may then be programmed with an increased value so that the delay cell controlled by the register has an increased delay that is still within its range (-818-), and the first test (and second test, if appropriate) may be repeated. The increased programmed value is marked as fail or pass. When all the programmable values of the register have been tested (-816-), the results of the programmed values are checked (-820-). If all the programmed values failed the tests, a failure is reported (-822-) and the method exits. If not all the programmed values failed the tests, the values which passed the tests are reported (-824-) and the method exits.

### Bidirectional Signals

The foregoing description has focused on separate conductors 8 and 10, each carrying its own signal. However, embodiments of the invention are equally applicable to the case of a single conductor electrically coupling output channel 12 of controller 4 to input channel 22 of device 6 and output channel 32 of device 6 to input channel 36 of controller 4. Within controller 4, the output of programmable output buffer 28 and the input to input buffer 40 will be electrically coupled. Within device 6, the output of channel 32 and the input to channel 22 will be electrically coupled. Any suitable technique may be used to ensure that only one of output channel 12 and output channel 32 sends a signal on the single conductor at any given time, including, for example, the known techniques of open drain outputs and high impedance outputs.

### Groups of Conductors

The foregoing description has focused on single conductors 8 and 10. In the foregoing description, each conductor had its own input channel and output channel, with the channels in controller 4 being controlled by registers. However, it will be understood that when a group of conductors are similar, controller 4 may have a single input-delay control register to control the input channels for the conductors in the group, and a single output-delay control register and a single driving impedance control register to control the output channels for the conductors in the group. The similarity between the conductors in a group may include, for example, similarity in the topology of the traces, similarity in the switching behavior of the signals, and similarity in the protocols of the signals, when applicable. For example, if the address signals are represented by 64 bits, then the 64 conductors carrying those bits may be considered as part of the same group, and controller 4 may have a single output-delay control register and a single driving impedance control register to control the output channels for the 64 conductors of the address signals.

### Exemplary Apparatus

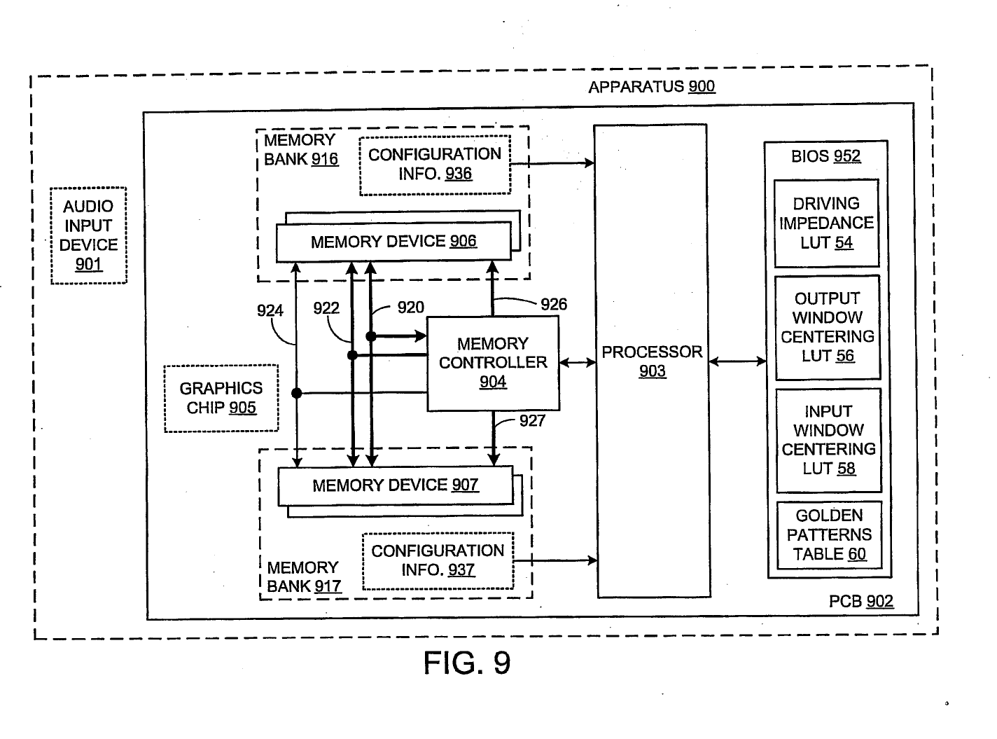

An exemplary apparatus 900 is shown in FIG. 9, according to some embodiments of the invention Apparatus 900 may comprise a printed circuit board (PCB) 902. Apparatus 900 may optionally comprise an audio input device 901. Well-known components and circuits of apparatus 900 are not shown in FIG. 9 so as not to obscure the invention.

A non-exhaustive list of examples for apparatus 900 includes a desktop personal computer, a server computer, a laptop computer, a notebook computer, a hand-held computer, a personal digital assistant (PDA), a mobile telephone, and the like, and any embedded application with a high-speed bus and memory subsystem.

A processor 903, a basic input/output system (BIOS) device 952, a memory controller 904, a memory bank 916 and an optional memory bank 917 may be installed upon PCB 902. (In some embodiments, memory controller 904 may be part of processor 903.) A graphics chip 905 may optionally be installed upon PCB 902. Additional components that may also be installed upon PCB 902 are not shown so as not to obscure the invention.

A non-exhaustive list of examples for processor 903 includes a central processing unit (CPU), a digital signal processor (DSP), a reduced instruction set computer (RISC), a complex instruction set computer (CISC) and the like. Moreover, processor 903 may be part of an application specific integrated circuit (ASIC) or may be a part of an application specific standard product (ASSP).

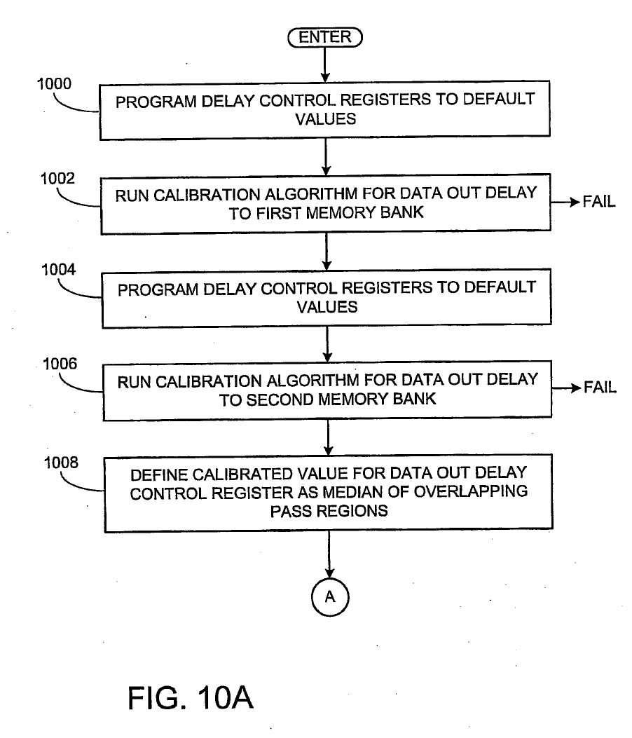

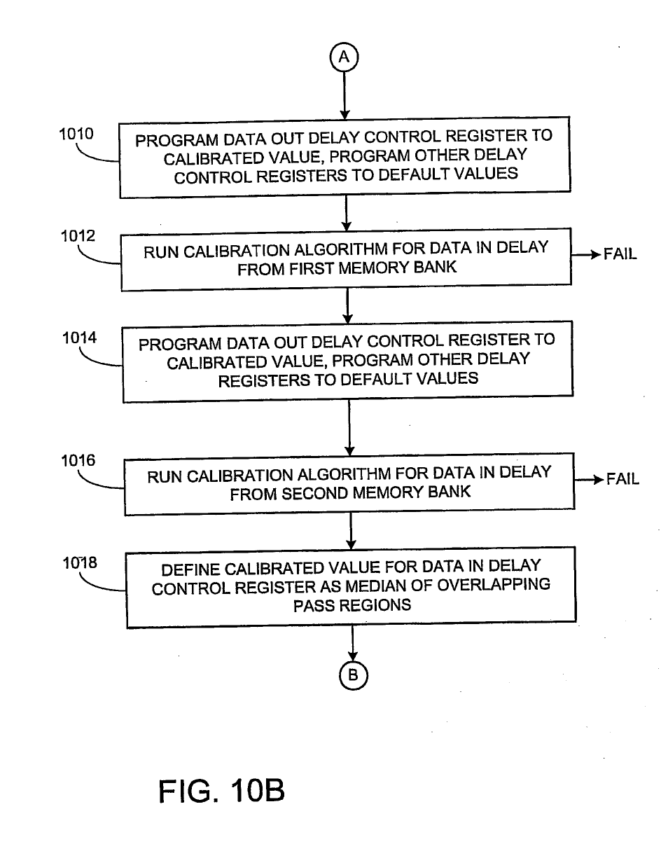

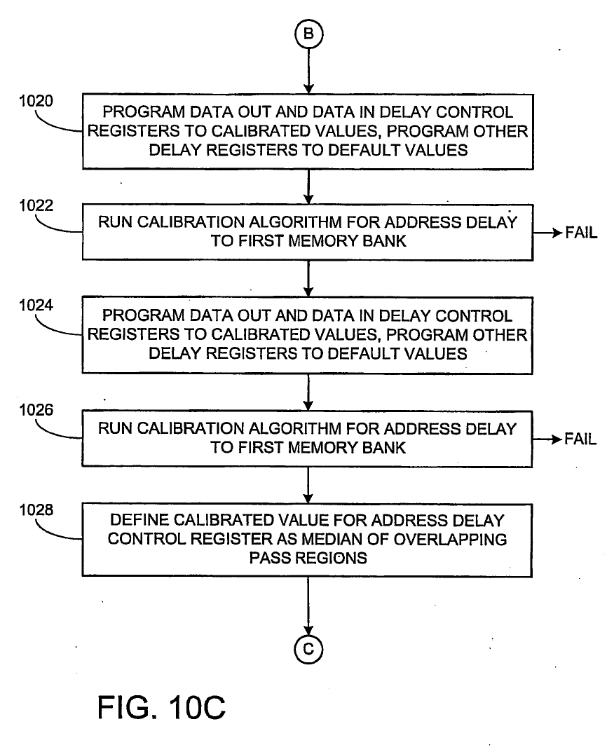

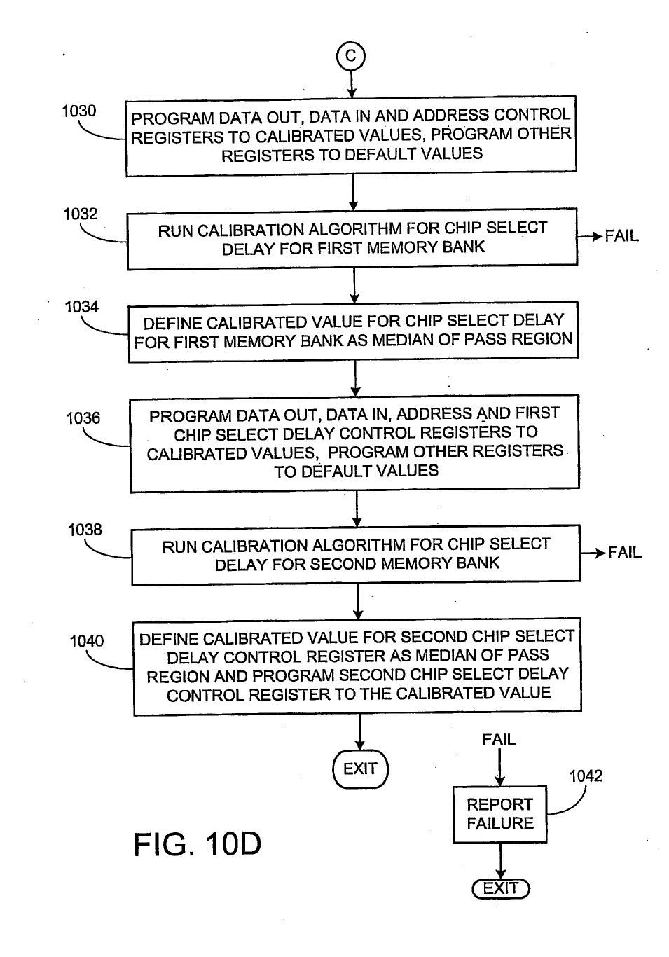

A non-exhaustive list of examples for BIOS device 952 includes a flash memory, an electrically erasable programmable read only memory (EEPROM), and the like. BIOS device 952 may comprise software modules to implement the methods of FIG. 6, FIGS. 10A-10D, and FIG. 8.

A non-exhaustive list of examples for memory controller 904 includes a bus bridge, a peripheral component interconnect (PCI) north bridge, a PCI south bridge, an accelerated graphics port (AGP) bridge, a memory interface device and the like, or a combination thereof. Moreover, memory controller 904 may be part of an application specific integrated circuit (ASIC) or part of a chip set or a part of an application specific standard product (ASSP).

Either or both of memory banks 916 and 917 may be a removable module, such as, for example, a dual in line memory module (DIMM), a small outline dual in line memory module (SODIMM), a single in line memory module (SIMM), a RAMBUS in line memory module (RIMM), and the like. Alternatively, either or both of memory banks 916 and 917 may be non-removable, e.g., may be permanently attached to PCB 902.

Memory banks 916 and 917 may comprise one or more memory devices 906 and 907, respectively. A non-exhaustive list of examples for memory devices 906 and 907 includes synchronous dynamic random access memory (SDRAM) devices, RAMBUS dynamic random access memory (RDRAM) devices, double data rate (DDR) memory devices, static random access memory (SRAM), and the like.

BIOS device 952 is a particular example of memory 52 of FIG. 1, and memory controller 904 is a particular example of controller 4 of FIG. 1, and memory devices 906 and 907 are particular examples of devices 6 of FIG. 1. Therefore, the following description will focus on the programming of registers in memory controller 904 that control input and output channels in memory controller 904 of signals between memory controller 904 and memory devices 906 and 907.

Memory controller 904 may be coupled to memory devices 906 and memory devices 907 through various groups of conductors. For a group of one or more conductors carrying one or more output signals, memory controller 904 may comprise one or more output channels (not shown) similar to output channel 12 of FIG. 1. For a group of one or more conductors carrying one or more input signals, memory controller 904 may comprise one or more input channels (not shown) similar to input channel 36 of FIG. 1.

One group of conductors 920 may carry memory data-in (MDIN) signals to read data from memory devices 906 and/or memory devices 907. Conductors 920 may also carry memory data-out (MDOUT) signals to write data to memory devices 906 and/or memory devices 907. Memory controller 904 may comprise a single driving impedance control register and an optional single output-delay control register to control the output channels of memory controller 904 that output the MDOUT signals on conductors 920. Similarly, memory controller 904 may comprise a single input-delay control register to control the input channels of memory controller 904 that receive the MDIN signals on conductors 920.

Another group of conductors 922 may carry address signals from memory controller 904 to memory devices 906 and/or memory devices 907. Memory controller 904 may comprise a single driving impedance control register and an optional single output-delay control register to control the output channels of memory controller 904 that output the address signals on conductors 922.

A single conductor 924 may carry a clock signal (similar to clock 20 and clock 24 of FIG. 1) from memory controller 904 to memory devices 906 and/or memory devices 907. Memory controller 904 may comprise a single driving impedance control register and an optional single output-delay control register to control the output channel of memory controller 904 that output the clock signal on conductor 924.

Another group of conductors 926 (927) may carry a “chip select” signal from memory controller 904 to memory devices 906 (907). The chip select signal is used to notify a particular memory device that the signals sent on the other conductors, namely the address and MDIN signals, are intended for that memory device. Memory controller 904 may comprise a single driving impedance control register and an optional single output-delay control register to control the output channels of memory controller 904 that output the chip select signals on conductors 926 and another single driving impedance control register and another optional single output-delay control register to control the output channels of memory controller 904 that output the chip select signals on conductors 927.

### Exemplary Calibration Sequence

FIGS. 10A-10D are flowchart illustrations of an exemplary calibration sequence for the digital values to be programmed to the delay control registers of memory controller 904, according to some embodiments of the invention. The control registers affected by~the exemplary calibration sequence of FIGS. 10A-10D are:
a) the “data out delay control register”—the output-delay control register for the output channels of memory controller 904 that output the MDOUT signals on conductors 920 (calibration of which is described in FIG. 10A);
b) the “data in delay control register”—the input-delay control register for the input channels of memory controller 904 the receive the MDIN signals on conductors 920 (calibration of which is described in FIG. 10B);
c) the “address delay control register”—the output-delay control register for the output channels of memory controller 904 that output the address signals on conductors 922 (calibration of which is described in FIG. 10C);
d) the “first chip select control register”—the output-delay control register for the output channels of memory controller 904 that output the chip select signals on conductors 926 to memory devices 906 (calibration of which is described in FIG. 10D); and
e) the “second chip select control register”—the output-delay control register for the output channels of memory controller 904 that output the chip select signals on conductors 927 to memory devices 907 (calibration of which is described in FIG. 10D).

When the sequence of FIGS. 10A-10D is called during the creation of a production BIOS (as in FIG. 5), the registers are already programmed by processor 903 with values from the lookup tables in BIOS device 952, the values having been selected by processor 903 from the tables according to configuration information 936 and 937 stored in memories, such as, for example, EEPROM, flash memory, and the like. For example, when memory bank 916 and/or memory bank 917 is a DIMM memory, the protocol used to read the configuration information 936 and 937 may be the Serial Presence Detect (SPD) protocol.

Similarly, when the sequence of FIGS. 10A-10D is called during power-up calibration or recurring calibration to compensate for changes (as in FIG. 6), the registers are already programmed, either with values from lookup tables in BIOS device 952 selected according to configuration information 936 and 937, or with values determined by a previous call to the calibration sequence of FIGS. 10A-10D.

A calibration algorithm may be performed for the value of the “data out delay control register” where the delay control registers of memory controller 904 may be programmed to the default values (-1000-) and memory data-out signals (MDOUT) are sent to memory devices 906 (-1002-). An exemplary calibration algorithm is described hereinabove with respect to FIG. 8. As is explained hereinabove with respect to FIG. 8, the calibration algorithm may determine one or more values for the “data out delay control register” at which the input channels of memory devices 906 correctly sample logic levels of the MDOUT signals on conductors 920.

The delay control registers of memory controller 904 may be programmed to the default values (-1004-). The calibration algorithm may be repeated for the value of the “data out delay control register”, where this time, memory data-out (MDOUT) signals are sent to memory devices 907 (-1006-). This time, the calibration algorithm may determine one or more values for the “data out delay control register” at which the input channels of memory devices 907 correctly sample logic levels of the MDOUT signals on conductors 920.

If some of the values determined by the calibration algorithm in -1002- and -1006- define overlapping regions of values for which the tests of the algorithm pass, then the calibrated value for the “data out delay control register” may be selected as the median of these overlapping values (-1008-).

The “data out delay control register” may then be programmed with the calibrated value, and the other delay control registers may be programmed with the default values (-1010-).

A calibration algorithm may be performed for the value of the “data in delay control register” where memory data-in signals (MDIN) are received from memory devices 906 (-1012-). The calibration algorithm may determine one or more values for the “data in delay control register” at which the input channels of memory controller 904 correctly sample logic levels of the MDIN signals on conductors 920 from memory devices 906.

The “data out delay control register” may then be programmed with the calibrated value, and the other delay control registers may be programmed with the default values (-1014-). The calibration algorithm may be repeated for the value of the “data in delay control register”, where this time, memory data-in (MDIN) signals are received from memory devices 907 (-1016-). This time, the calibration algorithm may determine one or more values for the “data in delay control register” at which the input channels of memory controller 904 correctly sample logic levels of the MDIN signals on conductors 920 from memory devices 907.

If some of the values determined by the calibration algorithm in -1012- and -1016- define overlapping regions of values for which the tests of the algorithm pass, then the calibrated value for the “data in delay control register” may be selected as the median of these overlapping values (-1018-).

The “data out delay control register” and “data in delay control register” may then be programmed with the calibrated values, and the other delay control registers may be programmed with the default values (-1020-).

A calibration algorithm may be performed for the value of the “address delay control register” (-1022-). The calibration algorithm may determine one or more values for the “address delay control register” at which the input channels of memory devices 906 correctly sample logic levels of the address signals on conductors 922.

The “data out delay control register” and “data in delay control register” may then be programmed with the calibrated values, and the other delay control registers may be programmed with the default values (-1024-).

The calibration algorithm may be repeated for the value of the “address delay control register”, where this time, address signals are received from memory devices 907 (-1026-). This time, the calibration algorithm may determine one or more values for the “address delay control register” at which the input channels of memory devices 907 correctly sample logic levels of the address signals on conductors 922.

If some of the values determined by the calibration algorithm in -1022- and -1026- define overlapping regions of values for which the tests of the algorithm pass, then the calibrated value for the “address delay control register” may be selected as the median of these overlapping values (-1028-).

The “data out delay control register”, “data in delay control register” and “address delay control register” may then be programmed with the calibrated values, and the other delay control registers may be programmed with the default values (-1030-).

A calibration algorithm may be performed for the value of the “first chip select delay control register” (-1032-). The calibration algorithm may determine one or more values for the “first chip select delay control register” at which the input channels of memory devices 906 correctly sample logic levels of the chip select signals on conductors 926. The calibrated value for the first chip select delay control register“may be selected as the median of these values (-1034-).

The “data out delay control register”, “data in delay control register”, “address delay control register and first chip select delay control register” may then be programmed with the calibrated values, and the other delay control registers may be programmed with the default values (-1036-).

A calibration algorithm may be performed for the value of the “second chip select delay control register” (-1038-). The calibration algorithm may determine one or more values for the “second chip select delay control register” at which the input channels of memory devices 907 correctly sample logic levels of the chip select signals on conductors 927. The calibrated value for the “second chip select delay control register” may be selected as the median of these values, and the “second chip select delay control register” may be programmed to the calibrated value (-1040-).

If a test fails during execution of a calibration algorithm, the failure may be reported (-1042-).

### Delay Values and Golden Patterns for Exemplary Calibration Algorithm

In one example, the calibration algorithm of FIG. 8 was called from the calibration sequence of FIGS. 10A-10D for the apparatus of FIG. 9. In this example, the frequency of clock 924 was 133 MHz, although in other examples, the frequency may have other values, such as, for example, 100 MHz, 166 MHz, 200 MHz, 266 MHz, etc. For the case of the clock frequency being 133 MHz, clock 924 oscillates with a period T_{PERIOD}=7.519 nanoseconds. When memory bank 916 and memory bank 917 are DIMM memories, the latest time at which an MDIN signal on conductors 920 sent by memory bank 916 or memory bank 917 is stabilized following a rising edge of clock 924 (max(T_{CO2}+T_{PLH2}, T_{CO2}+T_{PHL2})) may be, for example, approximately 1.8 nanoseconds to approximately 4.2 nanoseconds, which is a range of approximately 2.4 nanoseconds. The precise value of (max(T_{CO2}+T_{PLH2}, T_{CO2}+T_{PHL2})) may depend, for example, on the number and type of memory devices 906 and memory devices 907.

In this example, the delays T_{PD2} introduced by the programmable delay cell of the input channels of memory controller 904 that receive the MDIN signals on conductors 920 (controlled by the “data in delay control register” at point -818- of the calibration algorithm of FIG. 8) may have the following values:

| | Relative Delay |
|---|---|
| Delay | from Center |
| (picoseconds) | (picoseconds) |
| 0 | −2000 |
| 250 | −1750 |
| 500 | −1500 |
| 750 | −1250 |
| 1000 | −1000 |
| 1250 | −750 |
| 1500 | −500 |
| 1750 | −250 |
| 2000 | 0 |
| 2250 | 250 |
| 2500 | 500 |
| 2750 | 750 |
| 3000 | 1000 |
| 3250 | 1250 |
| 3500 | 1500 |
| 3750 | 1750 |

where a delay T_{PD2} of 2000 picoseconds corresponds roughly to the center of the expected range for delay T_{PD2}.

Moreover, in this example, conductors 920 comprise 64 conductors, where each conductor represents one bit. The 64 bits of conductors 920 are divided into eight bytes, each byte comprising eight bits numbered 0 to 7. The topology of conductors 920 may be such that noise coupling and interference between conductors that belong to different bytes is substantially small. Therefore each byte may be tested separately for setup time violations and hold time violations.

Furthermore, the topology of conductors 920 may be such that for each byte, the bit numbered 3 is the most sensitive to interference and to noise coupled from the rest of the bits of that byte.

Therefore, the following golden patterns may be used for performing stress testing of setup time violations and hold time violations, for a group of conductors comprising a byte of conductors 920:

| | |
|---|---|
| WRITE | READ |

| | | bits | bit | bits | bit |
|---|---|---|---|---|---|
| Pattern | CLK | 7, 6, 5, 4, 2, 1, 0 | 3 | 7, 6, 5, 4, 2, 1, 0 | 3 |
| SETUP | 1 | 1 | 0 | | |
| | 2 | 0 | 1 | | |
| | 3 | 1 | 0 | 0 | 1 |
| | 4 | 0 | 1 | 1 | 0 |
| HOLD | 5 | 0 | 1 | 0 | 1 |
| | 6 | 0 | 1 | | |
| | 7 | 0 | 1 | | |
| | 8 | 0 | 0 | | |
| | 9 | 0 | 1 | 0 | 0 |
| | 10 | 0 | 0 | 0 | 1 |

In the exemplary stress test for setup time violations, memory controller 904 sends a byte to memory device 906 or 907, where bits 7,6,5,4,2,1 and 0 of the byte have the same logic value that changes at each of four successive clocks (clocks 1-4) and bit 3 of the byte has the opposite logic value at each of the four successive clocks. Bits 7,6,5,4,2,1 and 0 of the byte may create a lot of noise, and the test will pass if memory device 906 or 907 correctly receives the bit 3 at each of clocks 3, 4 and 5.

In the exemplary relax test for hold time violations, at clocks 5-10, memory controller 904 sends an unchanging logic value for bits 7,6,5,4,2,1 and 0 of the byte in order to settle the system. At clocks 5-7, an unchanging opposite logic value for bit 3 is sent, also to settle the system. The logic value of bit 3 is then changed at clocks 8 and 9, and the test will pass if memory device 906 or 907 correctly receives bit 3 at each of clocks 9 and 10.

### Programmable Delay Cell

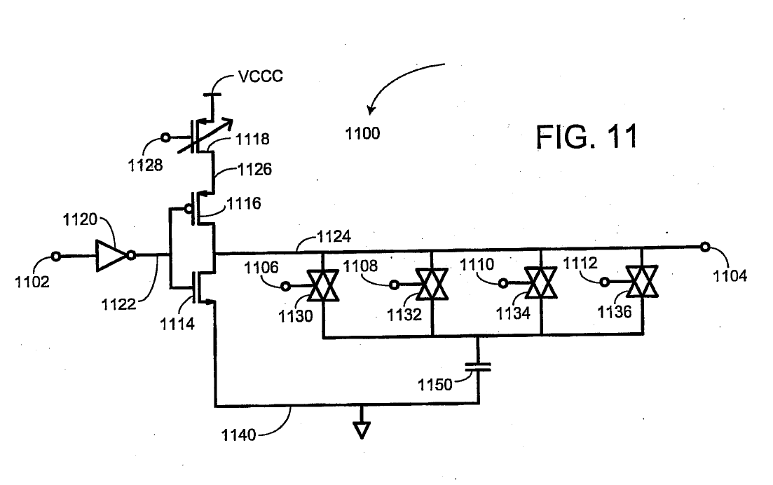

FIG. 11 is a simplified schematic illustration of an exemplary programmable delay cell 1100, in accordance with some embodiments of the invention. Programmable delay cell 1100 may be used to implement programmable delay cell 26 and/or programmable delay cell 42 of FIG. 1.

Programmable delay cell 1100 may receive an input signal 1102, control signals 1106, 1108, 1110, 1112 and 1128, and may generate an output signal 1104. Programmable delay cell 1100 may continuously sample the logic level of signal 1102, and may continuously output logic levels on a signal 1104 that are substantially equal to the logic levels sampled on signal 1102. When a change in the logic level of signal 1102 occurs, the logic level of signal 1104 may change accordingly after a time delay T_{PD}.

Time delay T_{PD} may be programmable within a time range, and may be set to one of sixteen time delays, according to the digital values of control signals 1106, 1108, 1110 and 1112. Moreover, control signal 1128 may enable continuous or fine grain tuning of the time delay T_{PD} selected by control signals 1106, 1108, 1110 and 1112. For example, control signal 1128 may be used so that time delay T_{PD} will be closer to a desired value. In another example, control signal 1128 may be used to apply corrections to time delay T_{PD} if it drifts from a desired value due, for example, to any or any combination of the following factors: variations in the supply voltage, variations in the ambient temperature, and variations in the temperature of controller 4. The corrections applied by control signal 1128 may be generated in response to output from a measurement system (not shown) to detect such variations.

Programmable delay cell 1100 may comprise a capacitor 1150. As will be explained hereinbelow, the digital values of control signals 1106, 1108, 1110 and 1112 may set time delay T_{PD} by controlling the impedance of a circuit that charges and discharges capacitor 1150. Moreover, control signal 1128 may adjust time delay T_{PD} by controlling the impedance of the circuit that charges capacitor 1150.

Programmable delay cell 1100 may comprise a switching transistor 1114, a switching transistor 1116, a variable impedance transistor 1118 and an inverter 1120.

Inverter 1120 may receive input signal 1102 and may output a signal 1122 having a logic level which is inverted from the logic level of signal 1102.

When the logic level of input signal 1102 is logic “0”, the logic level of signal 1122 is logic “1”, and conductor 1124 may be coupled to a low supply rail 1140 via a substantially low impedance Z_{L} presented by switching transistor 1114, and to a high supply rail VCCC via a substantially high impedance Z_{Z} presented by switching transistor 1116, thus practically decoupling conductor 1124 and conductor 1126.

When the logic level of input signal 1102 is logic “1”, the logic level of signal 1122 is logic “0”, and conductor 1124 may be coupled to low supply rail 1140 via a substantially high impedance Z_{H} presented by switching transistor 1114, and to high supply rail VCCC via a substantially low impedance Z_{H} presented by switching transistor 1116 and an impedance Z_{V} determined by control signal 1128 and presented by variable impedance transistor 1118.

However, for the simplicity of the explanation, if impedance Z_{Z} is substantially higher than impedances Z_{L} and Z_{H}, impedance Z_{Z} can be approximated as infinite impedance. Consequently, using this approximation, when the logic level of input signal 1102 is logic “0”, conductor 1124 may be coupled to low supply rail 1140 via the substantially low impedance Z_{L} presented by switching transistor 1114, and when the logic level of input signal 1102 is logic “1”, conductor 1124 may be coupled to high supply rail VCCC via the substantially low impedance Z_{H} presented by switching transistor 1116 and the impedance Z_{V} presented by variable impedance transistor 1118.

Programmable delay cell 1100 may comprise pass gates 1130, 1132, 1134 and 1136. Pass gates 1130, 1132, 1134 and 1136 may receive control signals 1106, 1108, 1110 and 1112, respectively as input. When the logic level of one of these control signals is logic “0”, the corresponding pass gate may couple conductor 1124 to capacitor 1150 with substantially high impedance Z_{Z}, thus practically de-coupling conductor 1124 from capacitor 1150. When the logic level of one of these control signals is logic “1”, the corresponding pass gate may couple conductor 1124 to capacitor 1150 with a substantially low impedance, for example Z₁ for pass gate 130, Z₂ for pass gate 132, Z₃ for pass gate 134 and Z₄ for pass gate 136. In one example, impedance Z₂ may be twice the impedance Z₁, impedance Z₃ may be twice the impedance Z₂, and impedance Z₄ may be twice the impedance Z₃.

It will be appreciated by persons of ordinary skill in the art, that conductor 1124 is coupled to capacitor 1150, with an impedance Z_{PASS} that is a combination of impedances in which of pass gates 1130, 1132, 1134 and 1136 couple conductor 1124 to capacitor 1150 (Z₁, Z₂, Z₃, Z₄ and Z_{Z}). Moreover, Z_{PASS} may have one of sixteen values, according to the combination of logic levels of control signals 1106, 1108, 1110 and 1112.

When input signal 1102 is asserted from a logic level “0” to a logic level “1”, electrical current will flow from the high supply rail VCCC via impedances Z_{V}, Z_{H} and Z_{PASS} to capacitor 1150. Consequently, the voltage level on capacitor 1150 and on conductor 1124, relative to the low supply rail, may increase. When the voltage on conductor 1124 becomes equal or higher than a predefined first threshold, output signal 1104 may be considered as having a logic level “1”. The time delay T_{PD} from the assertion of input signal 1102 to the voltage on conductor 1124 becoming equal or higher than a predefined first threshold, may be affected, at least in part, by the capacitance of capacitor 1150, by the voltage level of the high supply rail VCCC relative to the low supply rail, and by the values of impedances Z_{V}, Z_{H} and Z_{PASS}.

When input signal 1102 is de-asserted from logic level “1” to a logic level “0”, electrical current will flow from capacitor 1150 to low supply rail 1140 via impedances Z_{PASS} and Z_{L}. Consequently, the voltage level on capacitor 1150 and on conductor 1124, relative to the low supply rail, may decrease. When the voltage level on conductor 1124 becomes equal or lower than a predefined second threshold, output signal 1104 may be considered as having a logic level “0”. The time delay from the de-assertion of input signal 1102 to the voltage on conductor 1124 becoming equal or lower than a predefined second threshold may be affected, at least in part, by the capacitance of capacitor 1150 and by the values of impedances Z_{L} and Z_{PASS}.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

1. A programmable delay cell comprising:
a capacitor coupled to a low supply rail;
a conductor coupled to an output of said programmable delay cell; and
two or more pass gates coupled in parallel to said conductor and to said capacitor.

2. The programmable delay cell of claim 1, wherein an impedance of each of said pass gates is to be controlled by a respective control signal.

3. The programmable delay cell of claim 1, further comprising:
a variable impedance transistor coupled to a high supply rail and to said conductor, wherein an impedance of said variable impedance transistor is to be determined by a control signal.

4. A programmable delay cell comprising:
a conductor coupled to an output of said programmable delay cell; and
a variable impedance transistor coupled to a high supply rail and to said conductor, wherein an impedance of said variable impedance transistor is to be determined by a control signal.

5. The programmable delay cell of claim 4, wherein said control signal is set in response to output from a system to measure changes in the behavior of an integrated circuit comprising said programmable delay cell, said changes resulting, at least in part, from variations in a supply voltage to said integrated circuit, variations in an ambient temperature and variations in a temperature of said integrated circuit.

6. The programmable delay cell of claim 4, wherein said control signal is a continuous signal.

7. A controller comprising:
an output buffer to generate an electrical signal on a conductor coupled to said controller; and
a programmable delay cell coupled to said output buffer, wherein said programmable delay cell includes at least:
a capacitor coupled to a low supply rail;
a conductor coupled to an output of said programmable delay cell; and
two or more pass gates coupled in parallel to said conductor and to said capacitor.

8. The controller of claim 7, further comprising:
a register coupled to said programmable delay cell to store a value that determines a time delay introduced by said programmable delay cell.

9. The controller of claim 8, further comprising:
a memory to store one or more values to program to said register.

10. The controller of claim 7, wherein said controller is a memory controller.

11. The controller of claim 7, further comprising:
one or two registers coupled to said output buffer to store a first value that determines the source driving impedance of said output buffer and to store a second value that determines the sink driving impedance of said output buffer.

12. A controller comprising:
an output buffer to generate an electrical signal on a conductor coupled to said controller; and
a programmable delay cell coupled to said output buffer, wherein said programmable delay cell includes at least:
a conductor coupled to an output of said programmable delay cell; and
a variable impedance transistor coupled to a high supply rail and to said conductor, wherein an impedance of said variable impedance transistor is to be determined by a control signal.

13. The controller of claim 12, wherein said control signal is set in response to output from a system to measure changes in the behavior of said controller, said changes resulting, at least in part, from variations in a supply voltage to said controller, variations in an ambient temperature and variations in a temperature of said controller.

14. The controller of claim 12, further comprising:
a register coupled to said programmable delay cell to store a value that determines a time delay introduced by said programmable delay cell.

15. The controller of claim 14, further comprising:
a memory to store one or more values to program to said register.

16. The controller of claim 12, wherein said controller is a memory controller.

17. The controller of claim 12, further comprising:
one or two registers coupled to said output buffer to store a first value that determines the source driving impedance of said output buffer and to store a second value that determines the sink driving impedance of said output buffer.

18. A controller comprising:
an input buffer to receive an electrical signal from a conductor coupled to said controller; and
a programmable delay cell coupled to said input buffer, wherein said programmable delay cell includes at least:
a capacitor coupled to a low supply rail;
a conductor coupled to an output of said programmable delay cell; and
two or more pass gates coupled in parallel to said conductor and to said capacitor.

19. The controller of claim 18, further comprising:
a register coupled to said programmable delay cell to store a value that determines a time delay introduced by said programmable delay cell.

20. The controller of claim 19, further comprising:
a memory to store one or more values to program to said register.

21. The controller of claim 18, wherein said controller is a memory controller.

22. A controller comprising:
an input buffer to receive an electrical signal from a conductor coupled to said controller; and
a programmable delay cell coupled to said input buffer, wherein said programmable delay cell includes at least:
a conductor coupled to an output of said programmable delay cell; and
a variable impedance transistor coupled to a high supply rail and to said conductor, wherein an impedance of said variable impedance transistor is to be determined by a control signal.

23. The controller of claim 22, wherein said control signal is set in response to output from a system to measure changes in the behavior of said controller, said changes resulting, at least in part, from variations in a supply voltage to said controller, variations in an ambient temperature and variations in a temperature of said controller.

24. The controller of claim 22, further comprising:
a register coupled to said programmable delay cell to store a value that determines a time delay introduced by said programmable delay cell.

25. The controller of claim 24, further comprising:
a memory to store one or more values to program to said register.

26. The controller of claim 22, wherein said controller is a memory controller.

27. A printed circuit board comprising:
a graphics chip;
a controller including at least:
an output buffer to generate an electrical signal on a conductor coupled to said controller;
a programmable delay cell connected to said output buffer to directly provide input to said output buffer; and
a register coupled to said programmable delay cell to store an output-window-centering value that determines a time delay of said input relative to input to said programmable delay cell; and
a memory having programmed therein output-window-centering values for one or more configurations of devices to be installed on said printed circuit board and coupled to said controller.

28. The printed circuit board of claim 27, wherein said controller is a memory controller.

29. The printed circuit board of claim 28, further comprising:
one or more memory devices coupled to said memory controller, and wherein said memory controller is to drive said electrical signal to one or more of said one or more memory devices via said conductor.

30. The printed circuit board of claim 27, wherein said controller further includes:
one or two registers coupled to said output buffer to store a source-driving-impedance value that determines the source driving impedance of said output buffer and to store a sink-driving-impedance value that determines the sink driving impedance of said output buffer.

31. A printed circuit board comprising:
a graphics chip;
a controller including at least:
an input buffer to receive an electrical signal from a conductor coupled to said controller; and
a programmable delay cell connected to said input buffer to directly receive output of said input buffer; and
a register coupled to said programmable delay cell to store an input-window-centering value that determines a line delay of output of said programmable delay cell relative to said output of said input buffer; and
a memory having programmed therein input-window-centering values for one or more configurations of devices to be installed on said printed circuit board and coupled to said controller.

32. The printed circuit board of claim 31, wherein said controller is a memory controller.

33. The printed circuit board of claim 32, further comprising:
one or more memory devices coupled to said memory controller, and wherein one or more of said memory devices is to drive said electrical signal to said memory controller via said conductor.

34. A printed circuit board comprising:
a graphics chip;
a controller including at least a programmable delay cell, said programmable delay cell including at least:
a capacitor coupled to a low supply rail;
a conductor coupled to an output of said programmable delay cell; and
two or more pass gates coupled in parallel to said conductor and to said capacitor.

35. The printed circuit board of claim 34, wherein an impedance of each of said pass gates is to be controlled by a respective control signal.

36. The printed circuit board of claim 34, wherein said programmable delay cell further includes:
a variable impedance transistor coupled to a high supply rail and to said conductor, wherein an impedance of said variable impedance transistor is to be determined by a control signal.

37. A printed circuit board comprising:
a graphics chip;
a controller including at least a programmable delay cell, said programmable delay cell including at least:
a conductor coupled to an output of said programmable delay cell; and
a variable impedance transistor coupled to a high supply rail and to said conductor, wherein an impedance of said variable impedance transistor is to be determined by a control signal.

38. The printed circuit board of claim 37, wherein said control signal is set in response to output from a system to measure changes in the behavior of said controller, said changes resulting, at least in part, from variations in a supply voltage to said controller, variations in an ambient temperature and variations in a temperature of said controller.

39. The printed circuit board of claim 37, wherein said control signal is a continuous signal.

40. A computer apparatus comprising:
an audio input device; and
a printed circuit board comprising:
a memory controller including at least:
output-delay control registers to store output-window-centering values affecting time delays introduced by first programmable delay cells directly into inputs of output buffers of said memory controller; and
input-delay control registers to store input-window-centering values affecting time delays introduced by second programmable delay cells directly into outputs of data input buffers of said memory controller; and
a basic input/output system device having programmed therein output-window-centering values and input-window-centering values for one or more configurations of memory devices to be installed on said printed circuit board and coupled to said memory controller.

41. The apparatus of claim 40, wherein said memory controller further includes:
driving impedance control registers to store source-driving-impedance values and sink-driving-impedance values for said output buffers.

42. The apparatus of claim 41, wherein said basic input/output system device has programmed therein source-driving-impedance values and sink-driving-impedance values for said one or more configurations of memory devices.

43. A method comprising:
determining a time delay introduced by a programmable delay cell into a signal by controlling impedances of pass gates internal to said programmable delay cell.

44. The method of claim 43, further comprising:
adjusting said time delay by controlling a variable impedance of a variable impedance transistor internal to said programmable delay cell.

45. The method of claim 44, wherein controlling said variable impedance includes at least controlling said variable impedance in response to output from a system to measure changes in the behavior of an integrated circuit comprising said programmable delay cell, said changes resulting, at least in part, from variations in a supply voltage to said integrated circuit, variations in an ambient temperature and variations in a temperature of said integrated circuit.

46. A method comprising:
determining a time delay introduced by a programmable delay cell into a signal by controlling a variable impedance of a variable impedance transistor internal to said programmable delay cell.

47. The method of claim 46, further comprising:
adjusting said time delay by controlling impedances of pass gates internal to said programmable delay cell.

48. The method of claim 46, wherein controlling said variable impedance includes at least controlling said variable impedance in response to output from a system to measure changes in the behavior of an integrated circuit comprising said programmable delay cell, said changes resulting, at least in part, from variations in a supply voltage to said integrated circuit, variations in an ambient temperature and variations in a temperature of said integrated circuit.

49. A method comprising:
for one or more configurations of devices to be installed on printed circuit boards, determining values to be programmed to registers of controllers to be installed on said printed circuit boards,
where said registers affect tiring of signals between said controllers and said devices once said controllers and said devices are installed on said printed circuit boards by affecting one or more of the following: driving impedances of output buffers of said controllers, time delays introduced by first programmable delay cells directly into inputs of said output buffers and time delays introduced by second programmable delay cells directly into outputs of input buffers of said controllers.

50. The method of claim 49, further comprising:
storing said values in memories to be installed on said printed circuit boards.

51. The method of claim 49, further comprising:
determining calibrated values to be programmed to said registers based on timing of signals between said controllers and said devices once said controllers and said devices are installed on a particular type of printed circuit board; and
storing said calibrated values in memories to be installed on said particular type of printed circuit board.

52. A method comprising:
programming digital values to registers of a controller, said digital values retrieved from a memory based on configuration information regarding one or more devices,
wherein said registers affect timing of signals between said controller and said devices by affecting one or more of the following: time delays introduced by first programmable delay cells directly into inputs of output buffers of said controller and time delays introduced by second programmable delay cells directly into outputs of input buffers of said controller.

53. The method of claim 52, further comprising:
bringing said controller and said devices to operation conditions; and
performing one or more tests that said signals are accurately received.

54. The method of claim 53, wherein said one or more tests test violations of setup time restrictions and hold time restrictions of input channels of said devices.

55. The method of claim 53, wherein said one or more tests test violations of setup time restrictions and hold time restrictions of input channels of said controller.

56. The method of claim 53, wherein performing one or more tests includes at least:
performing one or more stress tests on said controller and said devices; and
if said one or more stress tests fail, performing one or more relaxed tests on said controller and said devices.

57. The method of claim 53, wherein performing said one or more tests includes at least:
driving a particular pattern on signals from said controller to said devices; and
checking whether portions of said particular pattern are accurately received by said devices.

58. A method comprising:
determining calibrated digital window centering values for registers of a controller by testing timing of signals between said controller and one or more devices,
wherein said registers affect said timing by affecting one or more of the following: time delays introduced by first programmable delay cells directly into inputs of output buffers of said controller and time delays introduced by second programmable delay cells directly into outputs of input buffers of said controller.

59. The method of claim 58, wherein determining said calibrated digital window centering values is performed on a recurring basis.

60. The method of claim 58, wherein testing timing of said signals includes at least:
for each test value in a set of sequential test values:
setting a particular one of said registers to said test value,
driving a particular pattern on signals from said controller to said devices; and
checking whether portions of said particular pattern are accurately received by said devices,
wherein the test value of said set closest to a median of test values of said set for which said portions are accurately received is determined to be a calibrated digital window centering value for said particular register.

61. An article comprising a storage medium having stored thereon instructions that, when executed by a computing platform, result in:
testing timing of signals between a controller and one or more devices for violations of setup time restrictions and hold time restrictions of input channels of said controller and said one or more devices by driving particular patterns on said signals from said controller to said one or more devices and checking whether portions of said particular pattern are accurately received by said one or more devices.

62. The article of claim 61, wherein said instructions further result in:
repeating said testing a register of said controller set to a test value in a set of sequential test values; and
programming said register with the test value of said set that is closest to a median of test values of said set for which said portions are accurately received.

63. The article of claim 62, wherein said register controls a time delay introduced by a programmable delay cell of said controller into an output signal of said controller.

64. The article of claim 62, wherein said register controls a time delay introduced by a programmable delay cell of said controller into an input signal of said controller.
